(19) United States
(12) Patent Application Publication
(10) Pub. No.: US 2007/0035346 A1
(43) Pub. Date: Feb. 15, 2007

(54) Variable impedance circuit using cell arrays

(75) Inventor: Hendrik Visser, Wijchen (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS, N.V., Eindhoven (NL)

(21) Appl. No.: 10/571,163

(22) PCT Filed: Sep. 7, 2004
(86) PCT No.: PCT/IB04/51708

§ 371 Date: Nov. 1, 2006

Related U.S. Application Data
(60) Provisional application No. 60/501,905, filed on Sep. 10, 2003.

(51) Int. Cl. H03L 7/00

(52) U.S. Cl. 331/16

(57) ABSTRACT

In a voltage control circuit (100), an array (500) of circuit elements is used to drive a variable capacitor controlling the frequency of a voltage controlled oscillator (110) (VCO). The array (500) has a plurality of cells (600), at least one output, a plurality of coarsesetting inputs (383-388) and a plurality of fine-setting inputs (380-382). Both types of inputs are adapted to enable selectable combinations of the cells (600). The VCO (110) is adapted to operate at a plurality of bit-addressable reference frequencies ranging over a plurality of frequency bands. The address control circuit (130) establishes one of the plurality of frequency bands by controlling the coarse-setting inputs (383-388), and also establishes one of the frequency bands by controlling the fine-setting inputs. In one example, the address control circuit is used to set a frequency band for the VCO circuit (100) and an analog signal is used to tune to a desired frequency within the band.

The present invention is directed generally to a variable impedance integrated circuit and, more particularly, to a unary-switched variable impedance integrated circuit.

Since the advent of radio circuits and other circuit control applications, it has been desirable to provide controlled input signals such as those signals used to control frequency band selection and maintain specific frequencies. Control circuits such as these are particularly useful in applications such as communications devices, guidance systems, and feedback control systems such as phase-lock-loops (PLL) employing voltage controlled oscillators (VCO).

Controlling frequency has often proved difficult, since electronic operation of most equipment produces heat, friction and other environment altering factors causing frequency to shift unpredictably. These factors are often addressed by utilizing a VCO in a PLL to continuously compare the VCO output signal with an incoming reference signal, and correct for undesirable frequency-shifts.

A standard PLL usually includes a VCO, a loop filter (LPF), a phase comparison circuit (COMP), a reference frequency signal input, and an oscillation signal output. The output of the VCO is fed back into the input of the COMP along with a reference signal. The output of the COMP is fed into the loop filter. The output of the loop filter is connected to the input of the VCO.

As is well known, the operation of the phase locked loop is such that the phase comparison circuit compares the phase of the oscillation of the VCO output with the phase of the reference frequency signal, outputs an error signal indicating the error between the phases of the oscillation signal and the reference frequency signal, and supplies the error signal to the loop filter. The loop filter smoothes the error signal, outputs it as a control voltage, and supplies the control voltage to the VCO. In the VCO, the resonance frequency of an LC resonator circuit is controlled in correspondence to the control voltage supplied by the loop filter, and the frequency of the VCO output signal is adjusted to eliminate the error between the VCO output and the reference signal.

In a high frequency VCO, a band-switch is used to improve the oscillator performance. The band-switch adds discrete values of capacitance to the frequency-tuning element in the oscillator's LC tuning circuit. The number of steps is traditionally powers of 2(e.g., 2, 4, 8, 16, 32, 64 . . . ). The switching is done in a binary way. From band 31 to 32, 31 capacitors are switched off and another 32 are switched on. Any inaccuracy in the capacitor is added up and is clearly visible as an inaccurate frequency selection. The manufacturing process for integrated circuits (ICs) limits the matching of capacitors within the IC, and mismatch creates errors during band switching. The errors are often corrected by using a continuous-voltage controlled capacitor (varicap) or they can be accepted, and contribute to manufacturing yield losses. Both situations are undesirable. Extra tuning in the varicap impacts performance, again resulting in yield losses that ultimately affect production cost.

Therefore, it would be advantageous to provide voltage control circuits that do not have band switching errors leading to high production yield losses. It would further be advantageous to provide an improved capacitance switching-network that does not suffer from capacitor-matching induced switching errors.

Various aspects of the present invention are directed to ICs configured and arranged in a manner that addresses and overcomes the above-mentioned issues for radio circuits, guidance circuits, lock-in amplifiers, and other applications benefiting from the use of variable impedance circuits.

In one embodiment of the present invention, a voltage control circuit is provided, the circuit including an array having a plurality of cells, at least one output, a plurality of coarse-setting inputs and a plurality of fine-setting inputs. The coarse-setting and fine-setting inputs are adapted to enable selectable combinations of the cells. The voltage control circuit is adapted to operate at a selected one of a plurality of bit-addressable reference frequencies ranging over a plurality of frequency bands. An address control circuit is adapted to establish one of the plurality of frequency bands by controlling the plurality of coarse-setting inputs of the array and adapted to establish a reference frequency in one of the plurality of frequency bands by controlling the plurality of fine-setting inputs of the array.

In another embodiment, A VCO circuit includes a VCO adapted to operate at a selected one of a plurality of bit-addressable reference frequencies ranging over a plurality of frequency bands, and as defined by a data-programming circuit. An array having a plurality of equally-weighted cells is provided, having at least one cell with selectable lesser-weighted circuits, and having at least one output. A plurality of coarse-setting inputs enable selected ones of the plurality of equally-weighted cells, and a plurality of fine-setting inputs enable ones of the lesser-weighted circuits, the coarse-setting and fine-setting inputs being adapted to provide an array output responsive to selected combinations of the enabled equally-weighted cells and the enabled lesser-weighted circuits. An address control circuit is responsive to the data-programming circuit for controlling the array and selecting one of the plurality of frequency bands. By controlling the plurality of coarse-setting inputs of the array and controlling the plurality of fine-setting inputs of the array, the reference frequency is established.

Consistent with the above example embodiments, in another embodiment an analog circuit provides an extra-fine tuning control as another input to the voltage-controlled target circuit.

The above summary of the present invention is not intended to describe each embodiment or every implementation of the present invention. Advantages and attainments, together with a more complete understanding of the invention, will become apparent and appreciated by referring to the following detailed description and claims taken in conjunction with the accompanying drawings.

The invention may be more completely understood in consideration of the following detailed description of various embodiments of the invention in connection with the accompanying drawings, in which:

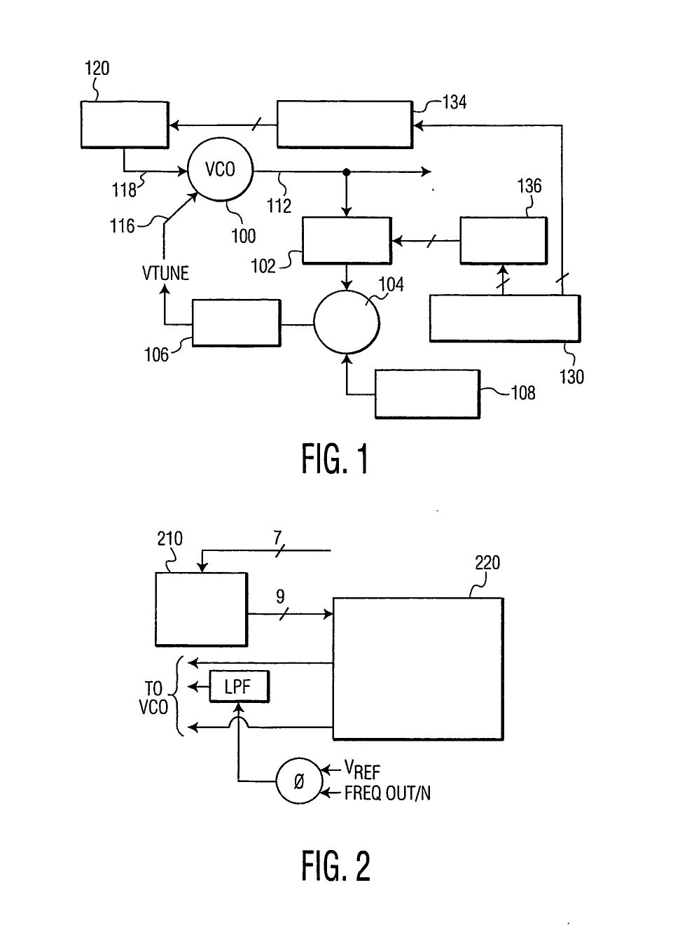

FIG. 1 is a block diagram of an example arrangement, including a VCO, in accordance with the present invention;

FIG. 2 is a block diagram of an example VCO voltage-tuning arrangement as may be applicable to the arrangement of FIG. 1, in accordance with the present invention;

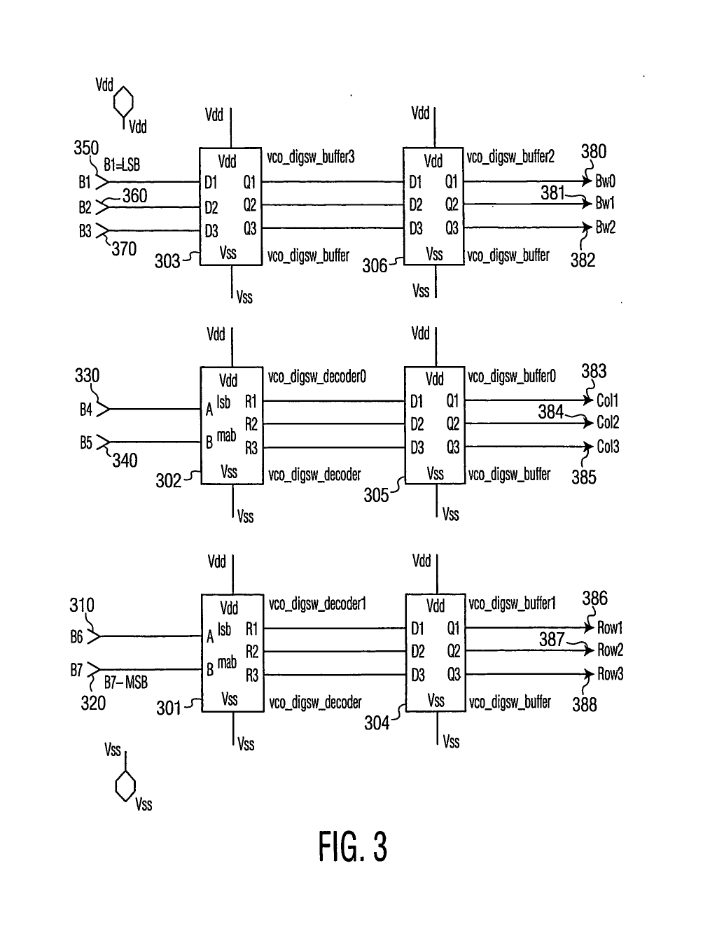

FIG. 3 is a block diagram of the 7-bit to 9-bit encoder of the arrangement of FIG. 2, in accordance with the present invention;

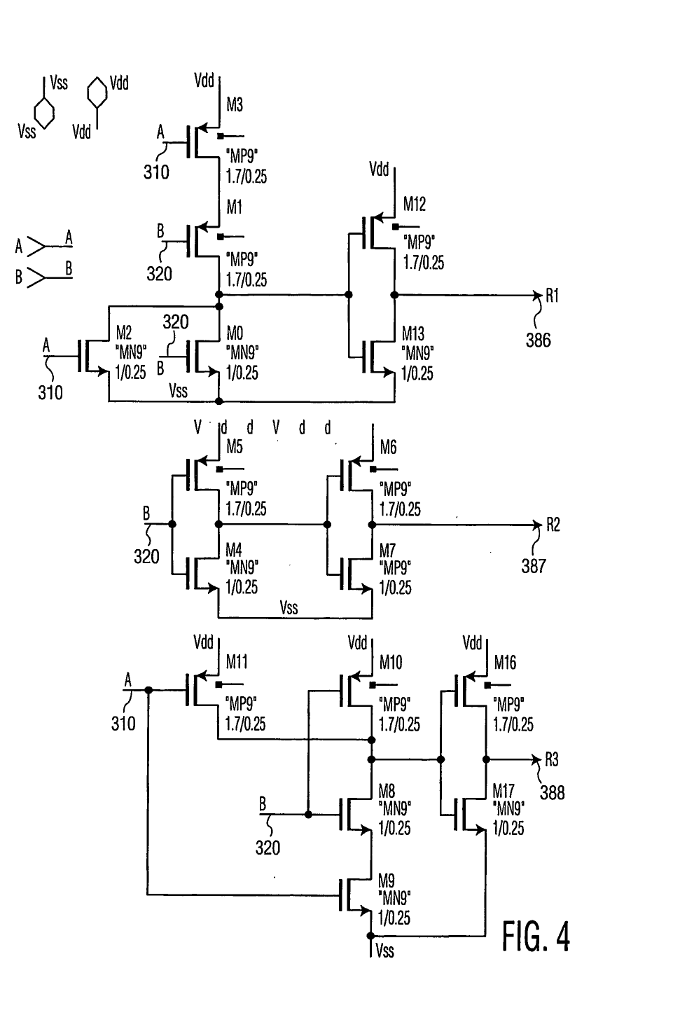

FIG. 4 is an expanded circuit diagram useful for exemplifying one of the encoders of FIG. 3, in accordance with the present invention;

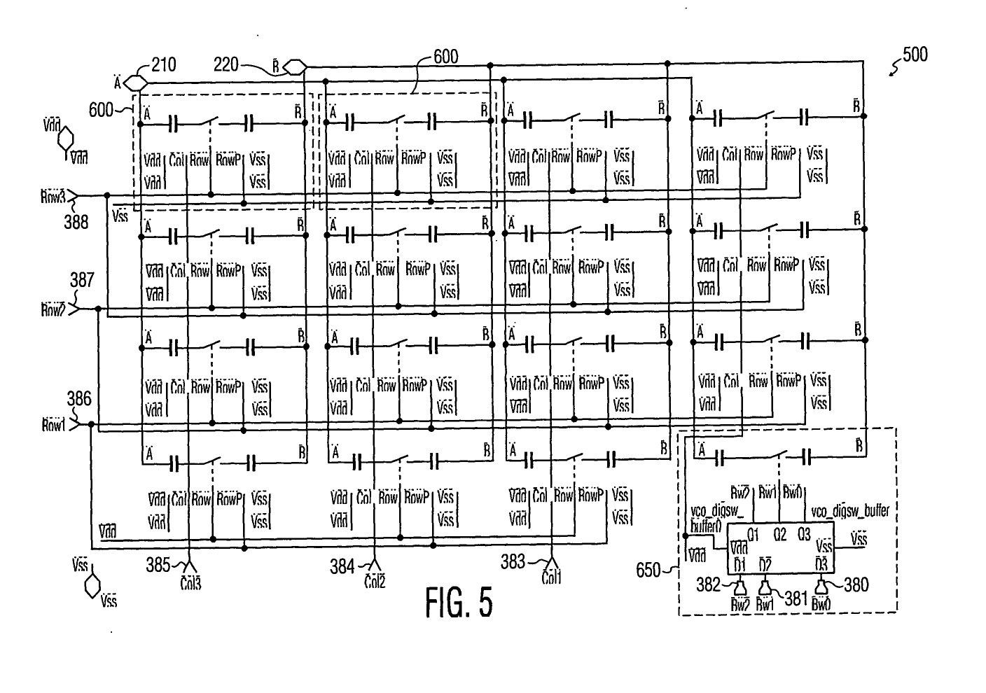

FIG. 5 is an example circuit diagram of the unary-capacitance switching-array of FIG. 2, in accordance with the present invention; and

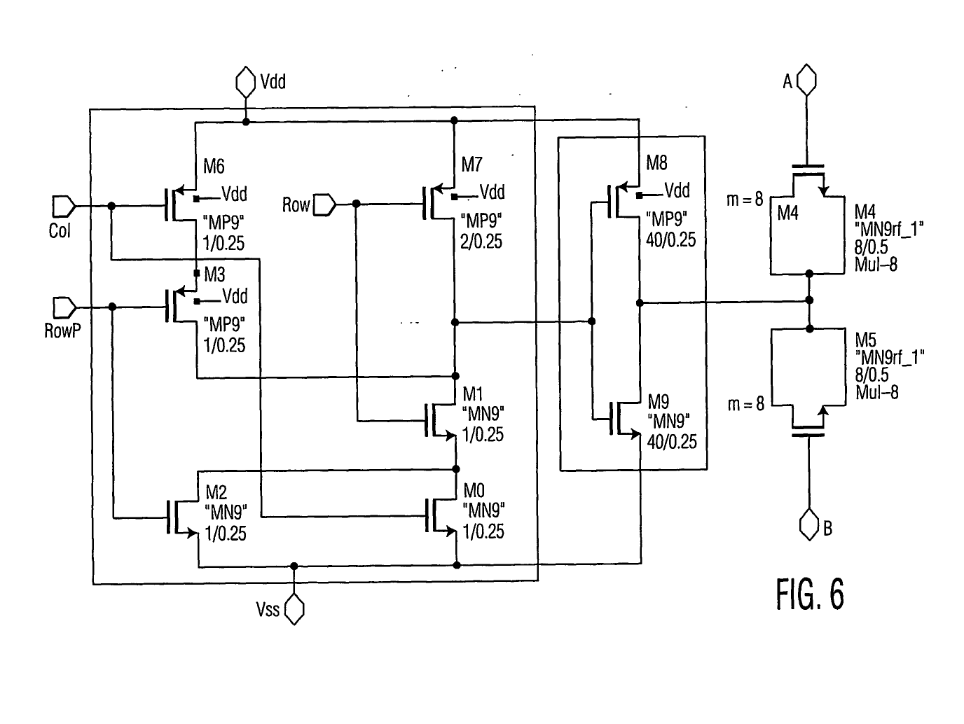

FIG. 6 is an example circuit diagram of a unary matrix element, in accordance with the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

The present invention is directed generally to a variable impedance integrated circuit and, more particularly, to a unary-switched variable impedance integrated circuit. Control circuits in accordance with the present invention may be used to control frequency-band selection and maintain specific frequencies, as well as perform other circuit control. Control circuits such as these are particularly useful in applications such as communications devices, guidance systems, and feedback control systems such as phase-locked loops (PLL) employing voltage controlled oscillators (VCO).

In accordance with the present invention, a first embodiment of the present invention is directed to an impedance-dependent circuit that has a voltage-controlled input at which a selected impedance is coupled for controlling an output of the circuit. The impedance-dependent circuit controls a voltage-controlled target circuit by way of an array having a plurality of cells, at least one output, and a plurality of coarse-setting and fine-setting inputs for enabling selectable combinations of the cells. The voltage-controlled target circuit operates at a selected one of a plurality of data-addressable reference frequencies, for example, ranging over a plurality of frequency bands. For driving the array, the impedance-dependent circuit also includes an address control circuit that controls the coarse-setting and the fine-setting inputs of the array. With these settings, a reference frequency is established at the output of the voltage-controlled target circuit.

In a more specific example embodiment, the present invention is directed to a VCO-based PLL that employs switched variable capacitor for frequency control of a VCO. A unary switchable variable capacitor circuit, in accordance with the present invention, is a capacitor circuit that switches a capacitor between an “on” state and an “off” state to either enable or disable the capacitor's effective capacitance value through a summation of respectively enabled capacitors. In accordance with the present invention, an array of such selectable switchable capacitors is provided for enabling any combination of capacitors to provide an effective capacitance value at an output of the array. The array includes a plurality of commonly-weighted capacitor cells with each such commonly-weighted cell providing the same capacitance value, and also includes at least one cell having different lesser-weighted capacitor cells with each such lesser-weighted cell providing respective capacitance values that are less than the capacitance value of the commonly-weighted cell. In this manner, any incremental increase or decrease in desired capacitance can be presented to the VCO (for voltage bias) by enabling the appropriate combinations of capacitor cells.

It is understood that manufacturing processes produce variation within elements designed to have a common value, and that the capacitors described herein will have values ranging within the available manufacturing tolerances. By providing a sufficiently-sized array for a given application (e.g., whether 7-cell array or a 25-cell array), the manufacturing-process variation is mitigated by the selectability of the designed capacitance values. For example, in certain VCO applications, the reference frequency is coarsely selected by using certain bits to address and enable commonly-weighted cells. Finer tuning is provided by using additional bits to address and enable certain of the different lesser-weighted cells.

For many applications (VCO and otherwise), with a sufficient number of such combinable capacitance cells, this above-described coarse/fine tuning approach adequate to control the voltage signal at the input of the impedance-dependent circuit. In other applications requiring more precision, also in accordance with the present invention, this coarse/fine tuning approach is complemented with an analog extra-fine voltage-adjustable input for more precisely tuning the VCO.

FIG. 1 illustrates such an application for a VCO-based PLL in which the above-discussed coarse/fine tuning approach is complemented with an analog extra-fine voltage-adjustable input for more precisely tuning a VCO 100 in a PLL circuit including a programmable divider 102, a phase-comparator 104, a low-pass filter 106 and a reference-frequency oscillation circuit 108, as would be conventional. In response to this PLL circuit, the VCO 100 is adapted to operate at a selected one of a plurality of data- (or bit) addressable reference frequencies ranging over a plurality of frequency bands, with the VCO output denoted by reference numeral 112. The PLL circuit is designed so that the output of the low-pass filter 106 is used to provide the above-discussed extra-fine voltage-adjustment to an input 116 of the VCO 100, whereas the above-discussed coarse/fine tuning is provided at another input 118 of the VCO 100. The input 118 of the VCO 100 is controlled by a frequency-select array 120. The frequency-select array 120 includes a number of cells, with each cell providing a capacitance value that can be selected for combining with the capacitance values of other cells in the array.

In a particular embodiment (not shown in FIG. 1), the array 120 has a number of equally-weighted cells as well as lesser-weighted cells, and the input 118 of the VCO 100 (output of the array 120) is responsive to selected combinations of the enabled equally-weighted and lesser-weighted cells. By enabling the appropriate combination of these cells, a relatively-specific reference frequency is defined for the VCO 100. The output of the low-pass filter 106 is then used to provide the above-discussed extra-fine voltage-adjustment to an input 116 of the VCO 100. An important advantage of this extra-fine adjustment is mitigation of adverse effects of the circuit-manufacturing process, as previously discussed.

Also shown in FIG. 1 is an example data programming circuit in the form of a micro-computer circuit 130. In this particular example application, the micro-computer circuit 130 is used to configure both the programmable divider 102 and a cell-enabling encoder 134. Included with the programmable divider 102 is a separate data register 136 (internal to the divider in another circuit design) that is separately addressed for storing data as presented from the micro-computer circuit 130. This stored data is used to set the divisor for the programmable divider 102 in the PLL feedback path. The cell-enabling encoder 134 includes an internal data register (external to the encoder in another circuit design) that is used to store cell-enabling data as presented from the micro-computer circuit 130. The encoder 134 translates this cell-enabling data for selecting combinations of the cells in the frequency-select array circuit 120.

In accordance with one embodiment of the present invention, the capacitors are arranged in a multidimensional array to reduce the complexity associated with the conversion from a first received format to a second desired format, such as, for example, converting from a binary format to a unary format. In a binary format, for example, switching from a binary 0111 to a binary 1000 involves turning off three capacitors, and turning on one capacitor. In a unary format, only a single capacitor is switched into the circuit (i.e. 01111111 to 11111111).

As a more particular example embodiment, FIG. 2 illustrates a 7-9 encoder 210 adapted to translate a 7-bit data word to a 9-bit address for enabling a desired capacitance as enabled and generated through a 16-cell switch array 220. The 7-bit data word is provided by a data programming circuit, such as the micro-computer circuit 130 of FIG. 1. In response to recognizing this 7-bit data word, the 7-9 encoder 210 produces the 9-bit address to enable selected combinations of capacitance circuitry in one or more of the 16 cells. The output of the array 220 is effectively a capacitance value presented at terminals A and B, as inputs to a tank circuit (not shown) within the VCO. The capacitance value presented at terminals A and B is combined with the output of the low-pass filter that is driving the voltage-tuning signal of the VCO. Together, this output of the array 220 and the output of the low-pass filter selects and tunes, respectively, the operating frequency of the VCO.

As shown in FIG. 2, the VCO voltage-tuning signal is a single signal with the respective capacitance values combined within the low-pass filter (from the array 220 and conventionally from the low-pass filter). In another implementation and as depending upon the particular design, the VCO tuning can be implemented with separate inputs (for example, as shown in FIG. 1) with the effect of the respective capacitance values combined within the VCO circuit or in a separate circuit between the VCO and the low-pass filter.

As shown and described in connection with the circuits of FIGS. 3, 4, 5 and 6, the array 220 can be implemented using four columns and four rows to provide the 16 cells. FIG. 3 illustrates a block diagram of the 7-bit to 9-bit encoder 210 for driving the array 220. The most significant bits (B7, B6) at terminals 310 and 320 are provided into decoder 301, and the next most significant bits (B5, B4) at terminals 330 and 340 are provided into decoder 302. The least significant bits (B3, B2 and B1) at terminals 350, 360, and 370 are latched directly into a D-type buffer 303, and do not need encoding in the present example. Outputs of decoder 301, decoder 302 and buffer 303 are input to (D-type flip-flop) buffers 304, 305 and 306, respectively. Depending on the application, clocked D-type flip-flop circuits can be used for latching the outputs of decoders 301 and 302. Outputs of buffer 304 provide coded matrix row signals at terminals 386, 387 and 388. Outputs of buffer 305 provide coded matrix column signals at terminals 383, 384 and 385. Outputs of buffer 306 provide buffered least significant bits at terminals 380, 381 and 382.

FIG. 4 is a circuit diagram exemplifying a type of implementation for one of the encoders 301 or 302 of FIG. 3, in accordance with the present invention. Using the encoder 301, for example, the two most significant bits (B7, B6) of the seven inputs to the encoder (210 of FIG. 2) are shown at terminals 320 and 310. On this encoder block depicted in FIG. 4, the letter A denotes the input of the signal B6 at terminal 310, and the letter B denotes the input of signal B7 at terminal 320. Viewing the buffer 304 transparently, R1 denotes the output signal for Row-1 at terminal 386, R2 denotes the output signal for Row-2 at terminal 387, and R3 denotes the output for Row-3 at terminal 388. The illustrated circuit implementation produces a signal Row-1 at terminal 386 that corresponds to the Boolean “OR” logic function for inputs at terminals “A” and “B”. The signal Row-2 at terminal 387 corresponds to a logical “1” when “B” is at a logical “1” and when “A” is at a logical “0”. The signal Row-3 at terminal 388 corresponds to the Boolean “AND” logic function for inputs “A” and “B”. In this manner, the encoding for row addressing of the array (220 of FIG. 2) is achieved via the two most-significant bits (B7, B6) being translated in 3 bits (R1, R2, R3) for the array according to the binary-logic functions as follows: R1=A+B; R2=B; and R3=A*B. The corresponding truth table is provided below:

| | |
|---|---|
| Input | Output |

| value | B | A | R3 | R2 | R1 |
|---|---|---|---|---|---|
| 0 | 0 | 0 | 0 | 0 | 0 |
| 1 | 0 | 1 | 0 | 0 | 1 |
| 2 | 1 | 0 | 0 | 1 | 1 |
| 3 | 1 | 1 | 0 | 1 | 1 |

With this type of encoding scheme for the encoder 302 of FIG. 3, the next most-significant bits (B5, B4) are translated to 3 column bits (C1, C2, C3) for the array. With a one-for-one straight translation for the least significant bits (B3-B1), a translation of the seven inputs (B7, B1) to the encoder (210 of FIG. 2) provides a 7-bit to 9-bit encoding scheme with translation of the 4 most-significant bits (B7-B4) into 3 “row” bits (R3-R1), 3 “column” bits (C1-C3), and along with the 3 least-significant bits.

FIG. 5 illustrates an expanded circuit diagram of an example array 500 that corresponds to the array 220 of FIG. 2. The array 500 is arranged in matrix form, with two switchable capacitors for each of the first fifteen cells 600, each of these fifteen cells being identically designed so as to provide a common capacitance value. Each block 600 is addressable by row and column according to the logic described in connection with FIGS. 3 and 4. The sixteenth block, designated as a least significant bit block 650, is illustrated at the bottom right corner of the array 220. As described earlier, the least significant three bits are not encoded in this example, and the block 650 uses weighted capacitors for the smallest three bits (8 levels) of capacitance resolution. The combination of fifteen repetitions of block 600 and block 650, using the logic and arrangement illustrated in the above figures, provides for a full 128 level capacitance discrimination with monotonic capacitance-value switching between successive levels of capacitance over the 128 level range.

Within each of the 15 unary (commonly-weighted) cells, at each capacitor the corresponding row bit and column bit are decoded using simple local logic, that is based on 2 row inputs and 1 column input. Basically, the cell logic is a function of the numerically-corresponding column and of the input from its numerically-corresponding row and the next row: when this row is active, use the column bits to select the capacitor; when the next row is active, make all capacitors active (ignore the column bit); and when no row is active, no capacitor is active (ignore the column bit).

The following truth table illustrates the overall translation of the this 7-bit to 9-bit encoding scheme for the example embodiment discussed above involving 7 bits, four of which are unary plus three bits that are weighted:

| | | | | | | | | | | | | | | | | | Decoded | | |
|---|---|---|---|---|---|---|---|---|---|---|---|---|---|---|---|---|---|---|---|
| | | | | | | | | | | | | | | | | | at | | |
| | | | | | | | | | | | | | | | | | capacitors | | |
| | Databus | | | | | | | Encoded | | | | | | | | | matrix | | |
| | 7-bits input | | | | | | | Row | | | Col | | | Bw | | | Unary-cells | | |
| | 7 | 6 | 5 | 4 | 3 | 2 | 1 | 3 | 2 | 1 | 3 | 2 | 1 | 3 | 2 | 1 | 15 | 14 | 13 |
| 0 | 0 | 0 | 0 | 0 | 0 | 0 | 0 | 0 | 0 | 0 | 0 | 0 | 0 | 0 | 0 | 0 | 0 | 0 | 0 |
| 1 | 0 | 0 | 0 | 0 | 0 | 0 | 1 | 0 | 0 | 0 | 0 | 0 | 0 | 0 | 0 | 1 | 0 | 0 | 0 |
| 2 | 0 | 0 | 0 | 0 | 0 | 1 | 0 | 0 | 0 | 0 | 0 | 0 | 0 | 0 | 1 | 0 | 0 | 0 | 0 |
| 3 | 0 | 0 | 0 | 0 | 0 | 1 | 1 | 0 | 0 | 0 | 0 | 0 | 0 | 0 | 1 | 1 | 0 | 0 | 0 |
| 4 | 0 | 0 | 0 | 0 | 1 | 0 | 0 | 0 | 0 | 0 | 0 | 0 | 0 | 1 | 0 | 0 | 0 | 0 | 0 |
| 5 | 0 | 0 | 0 | 0 | 1 | 0 | 1 | 0 | 0 | 0 | 0 | 0 | 0 | 1 | 0 | 1 | 0 | 0 | 0 |
| 6 | 0 | 0 | 0 | 0 | 1 | 1 | 0 | 0 | 0 | 0 | 0 | 0 | 0 | 1 | 1 | 0 | 0 | 0 | 0 |
| 7 | 0 | 0 | 0 | 0 | 1 | 1 | 1 | 0 | 0 | 0 | 0 | 0 | 0 | 1 | 1 | 1 | 0 | 0 | 0 |
| 8-15 | 0 | 0 | 0 | 1 | R | R | R | 0 | 0 | 0 | 0 | 0 | 1 | R | R | R | 0 | 0 | 0 |
| 16-23 | 0 | 0 | 1 | 0 | R | R | R | 0 | 0 | 0 | 0 | 1 | 1 | R | R | R | 0 | 0 | 0 |
| 24-31 | 0 | 0 | 1 | 1 | R | R | R | 0 | 0 | 0 | 1 | 1 | 1 | R | R | R | 0 | 0 | 0 |
| 32-39 | 0 | 1 | 0 | 0 | R | R | R | 0 | 0 | 1 | 0 | 0 | 0 | R | R | R | 0 | 0 | 0 |
| 40-47 | 0 | 1 | 0 | 1 | R | R | R | 0 | 0 | 1 | 0 | 0 | 1 | R | R | R | 0 | 0 | 0 |
| 48-55 | 0 | 1 | 1 | 0 | R | R | R | 0 | 0 | 1 | 0 | 1 | 1 | R | R | R | 0 | 0 | 0 |
| 56-63 | 0 | 1 | 1 | 1 | R | R | R | 0 | 0 | 1 | 1 | 1 | 1 | R | R | R | 0 | 0 | 0 |
| 64-71 | 1 | 0 | 0 | 0 | R | R | R | 0 | 1 | 1 | 0 | 0 | 0 | R | R | R | 0 | 0 | 0 |
| 72-79 | 1 | 0 | 0 | 1 | R | R | R | 0 | 1 | 1 | 0 | 0 | 1 | R | R | R | 0 | 0 | 0 |
| 80-87 | 1 | 0 | 1 | 0 | R | R | R | 0 | 1 | 1 | 0 | 0 | 1 | R | R | R | 0 | 0 | 0 |
| 88-95 | 1 | 0 | 1 | 1 | R | R | R | 0 | 1 | 1 | 1 | 1 | 1 | R | R | R | 0 | 0 | 0 |
| 96-103 | 1 | 1 | 0 | 0 | R | R | R | 1 | 1 | 1 | 0 | 0 | 0 | R | R | R | 0 | 0 | 0 |
| 104-111 | 1 | 1 | 0 | 1 | R | R | R | 1 | 1 | 1 | 0 | 0 | 1 | R | R | R | 0 | 0 | 1 |
| 112-119 | 1 | 1 | 1 | 0 | R | R | R | 1 | 1 | 1 | 0 | 1 | 1 | R | R | R | 0 | 1 | 1 |
| 120-127 | 1 | 1 | 1 | 1 | R | R | R | 1 | 1 | 1 | 1 | 1 | 1 | R | R | R | 1 | 1 | 1 |

| | Decoded at capacitors matrix | | | | | | | | | | | | | | |
|---|---|---|---|---|---|---|---|---|---|---|---|---|---|---|---|
| | Unary-cells | | | | | | LSB's | | | | | | | | |
| | 12 | 11 | 10 | 9 | 8 | 7 | 6 | 5 | 4 | 3 | 2 | 1 | 3 | 2 | 1 |
| 0 | 0 | 0 | 0 | 0 | 0 | 0 | 0 | 0 | 0 | 0 | 0 | 0 | 0 | 0 | 0 |
| 1 | 0 | 0 | 0 | 0 | 0 | 0 | 0 | 0 | 0 | 0 | 0 | 0 | 0 | 0 | 1 |
| 2 | 0 | 0 | 0 | 0 | 0 | 0 | 0 | 0 | 0 | 0 | 0 | 0 | 0 | 1 | 0 |
| 3 | 0 | 0 | 0 | 0 | 0 | 0 | 0 | 0 | 0 | 0 | 0 | 0 | 0 | 1 | 1 |
| 4 | 0 | 0 | 0 | 0 | 0 | 0 | 0 | 0 | 0 | 0 | 0 | 0 | 1 | 0 | 0 |
| 5 | 0 | 0 | 0 | 0 | 0 | 0 | 0 | 0 | 0 | 0 | 0 | 0 | 1 | 0 | 1 |
| 6 | 0 | 0 | 0 | 0 | 0 | 0 | 0 | 0 | 0 | 0 | 0 | 0 | 1 | 1 | 0 |
| 7 | 0 | 0 | 0 | 0 | 0 | 0 | 0 | 0 | 0 | 0 | 0 | 0 | 1 | 1 | 1 |
| 8-15 | 0 | 0 | 0 | 0 | 0 | 0 | 0 | 0 | 0 | 0 | 0 | 1 | R | R | R |
| 16-23 | 0 | 0 | 0 | 0 | 0 | 0 | 0 | 0 | 0 | 0 | 1 | 1 | R | R | R |
| 24-31 | 0 | 0 | 0 | 0 | 0 | 0 | 0 | 0 | 0 | 1 | 1 | 1 | R | R | R |
| 32-39 | 0 | 0 | 0 | 0 | 0 | 0 | 0 | 0 | 1 | 1 | 1 | 1 | R | R | R |
| 40-47 | 0 | 0 | 0 | 0 | 0 | 0 | 0 | 1 | 1 | 1 | 1 | 1 | R | R | R |
| 48-55 | 0 | 0 | 0 | 0 | 0 | 0 | 1 | 1 | 1 | 1 | 1 | 1 | R | R | R |
| 56-63 | 0 | 0 | 0 | 0 | 0 | 1 | 1 | 1 | 1 | 1 | 1 | 1 | R | R | R |
| 64-71 | 0 | 0 | 0 | 0 | 1 | 1 | 1 | 1 | 1 | 1 | 1 | 1 | R | R | R |
| 72-79 | 0 | 0 | 0 | 1 | 1 | 1 | 1 | 1 | 1 | 1 | 1 | 1 | R | R | R |
| 80-87 | 0 | 0 | 1 | 1 | 1 | 1 | 1 | 1 | 1 | 1 | 1 | 1 | R | R | R |
| 88-95 | 0 | 1 | 1 | 1 | 1 | 1 | 1 | 1 | 1 | 1 | 1 | 1 | R | R | R |
| 96-103 | 1 | 1 | 1 | 1 | 1 | 1 | 1 | 1 | 1 | 1 | 1 | 1 | R | R | R |
| 104-111 | 1 | 1 | 1 | 1 | 1 | 1 | 1 | 1 | 1 | 1 | 1 | 1 | R | R | R |
| 112-119 | 1 | 1 | 1 | 1 | 1 | 1 | 1 | 1 | 1 | 1 | 1 | 1 | R | R | R |
| 120-127 | 1 | 1 | 1 | 1 | 1 | 1 | 1 | 1 | 1 | 1 | 1 | 1 | R | R | R |

The above table assumes that the 7 bits of the databus, for 128 possible values (0-127), are feeding the inputs (B7-B1) to the encoder as if these 7-bits are weighted. Also, for those rows representing 8 values (e.g., 8-15), “R” is used in the above table to denote that the LSB values are repeated (no change) from the first 8 values (0-7) as shown in the table. In this manner, it is appreciated that the row corresponding to value 127 would, in each entry, be “1”. Further, it is appreciated that the header term “Encoded” at the top line of the truth table shows an intermediate step for addressing all 15 unary cells but with only 6 lines instead of 15. Effective encoding increases with the number of unary cells (now 4 bits). However, decoding at each unary cell is needed. But this decoding is repeated in a similar way for all unary cells. The “Bw” bits are the “weighted bits” for the uniquely weighted 16^{th} cell (for which the 3 LSB's just pass through the encoder). The “row” and “col” bits are the row and column bits. The 4 bits unary coding (bits 4. . . 7) creates 6 new encoded bits (row 1.3 and col 1.3). The header term “Decoded at capacitors matrix” denotes where the real capacitors are switched and with the LSB's again connected straight through the decoder with no decoding needed.

FIG. 6 is a circuit diagram of the representative block 600 of FIG. 5, which is a unary capacitance matrix element in accordance with the present invention. The block 600 provides a first unary capacitor 610 and a second unary capacitor 620 to be switched across the terminals A 210 and B 220 by decoding Row-3 388 and Col-3 385 signals through a decode circuit 630. After decoding, an inverter driver circuit 640 switches the capacitors 610 and 620 in or out of the effective capacitance that is used to set the voltage for the VCO.

Various modifications and additions can be made to the preferred embodiments discussed hereinabove without departing from the scope of the present invention. Accordingly, the scope of the present invention should not be limited by the particular embodiments described above, but should be defined only by the claims set forth below and equivalents thereof.

1. A voltage control circuit comprising: an array having a plurality of cells at least one output, a plurality of coarse-setting inputs and a plurality of fine-setting inputs the coarse-setting and fine-setting inputs being adapted to enable selectable combinations of the cells a voltage-controlled target circuit adapted to operate at a selected one of a plurality of bit-addressable reference frequencies ranging over a plurality of frequency bands; and an address control circuit adapted to establish one of the plurality of frequency bands by controlling the plurality of coarse-setting inputs of the array and adapted to establish a reference frequency in the established one of the plurality of frequency bands by controlling the plurality of fine-setting inputs of the array.

2. The voltage control circuit of claim 1, wherein the most of the cells in the array respectively include similarly-valued impedance-providing circuits.

3. The voltage control circuit of claim 2, wherein each of the similarly-valued impedance-providing circuits provides a capacitance value at said at least one output.

4. The voltage control circuit of claim 1, further including a digital-data circuit adapted to program the address control circuit and therein to set the coarse-setting and fine-setting inputs and enable combinations of the cells.

5. The voltage control circuit of claim 4, wherein the enabled combinations of the cells provide a weighted output value for controlling the voltage-controlled target circuit, the weighted output value corresponding to said at least one lesser-weight value combined with a multiple of the common-weight value.

6. The voltage control circuit of claim 1, further including an analog control circuit coupled to the voltage-controlled target circuit for providing a range of adjustment to the reference frequency, the range of adjustment corresponding to a weight value that is less than the least of the lesser-weight values.

7. The voltage control circuit of claim 1, wherein the array includes a plurality of equally-weighted cells each having a common-weight value and includes at least one fine-setting cell having at least one lesser-weight value that is less than the common weight.

8. The voltage control circuit of claim 1, wherein the array includes at least one fine-setting cell having at least one lesser-weight value and includes a plurality of equally-weighted cells each having a common-weight value, the common-weight value being a multiple of said at least one lesser-weight value.

9. The voltage control circuit of claim 1, wherein the plurality of cells include a plurality of commonly-weighted cells that are selected by the plurality of coarse-setting inputs, each of the commonly-weighted cells having a commonly-weighted value, and wherein another of the cells has at least one selectable circuit with the lesser-weight values, and wherein the commonly-weighted values have a deviation that is not greater than the least of the lesser-weight values.

10. The voltage control circuit of claim 1, wherein the array includes a fine-setting cell having selectable circuits having lesser-weight values and includes a plurality of equally-weighted cells each having a common-weight value, the common-weight value being a multiple of at least one of the selectable lesser-weight values.

11. The voltage control circuit of claim 10, wherein the coarse-setting inputs are adapted to enable selected ones of the plurality of equally-weighted cells, and the fine-setting inputs are adapted to enable selected ones of the plurality of the selectable circuits having lesser-weight values, therein enabling a combination of values useful for establishing the reference frequency in the established one of the plurality of frequency bands.

12. The voltage control circuit of claim 11, wherein the lesser-weight values are multiples of two.

13. The voltage control circuit of claim 11, wherein each of the lesser-weight values and the common-weight value are multiples of two.

14. The voltage control circuit of claim 11, wherein the common-weight value is twice as great as the greatest of the lesser-weight values.

15. The voltage control circuit of claim 11, wherein the common-weight values have a deviation that is not greater than the least of the lesser-weight values.

16. A VCO circuit, comprising: a VCO (110) adapted to operate at a selected one of a plurality of bit-addressable reference frequencies ranging over a plurality of frequency bands; an array having a plurality of equally-weighted cells, having at least cell with selectable lesser-weighted circuits, having at least one output, having a plurality of coarse-setting inputs adapted to enable selected ones of the plurality of equally-weighted cells, and having a plurality of fine-setting inputs adapted to enable ones of the lesser-weighted circuits, the coarse-setting and fine-setting inputs being adapted to provide an array output responsive to selected combinations of the enabled equally-weighted cells and the enabled lesser-weighted circuits; a data programming circuit and an address control circuit responsive to the data programming circuit and adapted to establish one of the plurality of frequency bands by controlling the plurality of coarse-setting inputs of the array and adapted to establish a reference frequency in the established one of the plurality of frequency bands by controlling the plurality of fine-setting inputs of the array.

17. The VCO circuit of claim 16, further including an analog control circuit coupled to the VCO for providing an extra-fine range of adjustment to the reference frequency.

18. A voltage control circuit comprising: an array having a plurality of cells, at least one output, a plurality of coarse-setting inputs and a plurality of fine-setting inputs the coarse-setting and fine-setting inputs being adapted to enable selectable combinations of the cells frequency-oscillation means for operating at a selected one of a plurality of bit-addressable reference frequencies ranging over a plurality of frequency bands; and means for establishing one of the plurality of frequency bands by controlling the plurality of coarse-setting inputs of the array and for establishing a reference frequency in the established one of the plurality of frequency bands by controlling the plurality of fine-setting inputs of the array.
